(19) United States
(12) Patent Application Publication
(10) Pub. No.: US 2012/0035056 A1
(43) Pub. Date: Feb. 9, 2012

(54) Nb-DOPED PEROVSKITE FLUX PINNING OF REBCO BASED SUPERCONDUCTORS BY MOCVD

(76) Inventors: TOLGA AYTUG, Knoxville, TN (US); Mariappan Parans Paranthaman, Knoxville, TN (US); Victor A. Maroni, Naperville, IL (US); Dean J. Miller, Darien, IL (US)

(21) Appl. No.: 12/850,115

(22) Filed: Aug. 4, 2010

(51) Int. Cl. H01L 39/00; H01L 39/24

(52) U.S. Cl. 505/150; 505/473; 427/62; 428/172

(57) ABSTRACT

A method of making a superconducting article that involves using MOCVD to deposit onto a uniaxially or biaxially textured surface an epitaxial layer that includes a superconducting material such as REBa₂Cu₃O₇ and a secondary phase comprising at least one dopant, the dopant including Nb, Ta and/or V, or combinations thereof.

### STATEMENT REGARDING FEDERALLY SPONSORED RESEARCH

The United States Government has rights in this invention pursuant to contract no. DE-AC05-000R22725 between the United States Department of Energy and UT-Battelle, LLC.

### FIELD OF THE INVENTION

The invention is drawn to flux pinning of REBCO based semiconductors using MOCVD techniques.

### BACKGROUND OF THE INVENTION

Methods for the preparation of films of high temperature superconductor (HTS) materials on various substrates are well known. The first HTS tapes suffered from unacceptably low critical current densities, a problem caused by poor alignment of grains in the HTS film or coating. Several techniques have subsequently been developed to fabricate wires or tapes wherein grain alignment is produced, such as Rolling-Assisted-Biaxially-Textured-Substrates (RABiTS). RABiTS substrates typically include a textured metal underlayer (for example, nickel or nickel alloy) and an epitaxial buffer layer (for example, Y₂O₃ and/or yttria-stabilized zirconia, YSZ, and/or cerium oxide, CeO₂).

A problem with HTS tapes and wires is that the critical current density (typically expressed as J_{c}) of the superconductor film decreases when the superconductor film is exposed to an external magnetic field. Since external magnetic fields (often as high as 5 Tesla, or higher) are prevalent in most commercial and industrial applications, there has been a significant effort in incorporating design features into the superconductor film that mitigate these current density losses. One method has been to introduce structural defects (i.e., pinning defects) into the superconductor film. The pinning defects have been found to significantly reduce current density losses in superconductor films in the presence of an external magnetic field.

Potential applications of high temperature superconductors that involve both electronic devices at the small scale, and high-current wires at the large scale rely upon magnetic flux pinning by material defects to provide optimal properties. These defects serve to prevent motion of the quantized magnetic filaments (supercurrent vortices) that permeate practical superconducting materials in the presence of a magnetic field. This motion may occur from a Lorentz-like force from an imposed transport current density, J, or even from thermal activation that causes a Brownian-like vortex motion, especially in high-temperature superconductors. There are several mechanisms by which vortices may be pinned, most of which rely on developing nanostructural features that interact with the individual flux lines by providing spatial variation of the thermodynamic free energy.

Flux pinning is the phenomenon that magnetic flux lines do not move (become trapped, or “pinned”) in spite of the Lorentz force acting on them inside a current-carrying Type II superconductor. Flux pinning is desirable in high-temperature ceramic superconductors to prevent “flux creep”, which can create a pseudo-resistance and depress both critical current density and critical field. Degradation of a high-temperature superconductor's properties due to flux creep is a limiting factor in the use of these superconductors.

In order to realize the full potential of high temperature superconducting wires (HTS coated conductors) for various commercial electric-power equipment, the flux pinning properties of REBa₂Cu₃O₇ films (REBCO, RE═Y or a rare earth element) need to be improved in a controlled, reproducible and practical fashion. In fact, these are the key requirements for scalable deposition approaches for producing large-scale, long-length, continuous conductors. Improvements in pinning efficiency not only enhance the critical current density (J_{c}) under high magnetic fields (B), but also may help reduce the field dependent anisotropy in J_{c} for in-field orientations ranging from parallel to the ab-plane to parallel to the c-axis. The latter advancement is especially important for such power utility applications as motors, generators, and transmission lines, where HTS cables experience varying magnetic field strengths and directions.

Flux pinning is possible when defects in the crystalline structure of the superconductor provide a lower energy site for magnetic vortices to reside. Physical methods (e.g., by laser scribing or photolithographic patterning) and chemical doping (e.g., with BaZrO₃) have been utilized to introduce pinning defects into the superconductor film. Recent research has focused on introducing such defects into superconducting films by growing superconducting films epitaxially on substrates possessing microstructural defects (e.g., phase-separated components). However, the common techniques currently capable of producing such phase-separated substrates are not commercially viable. For example, physical vapor deposition (PVD), pulsed laser deposition (PLD), molecular beam epitaxy (MBE), and atomic layer deposition (ALD) possess the significant drawbacks of being non-scalable, cost prohibitive, and industrially inefficient (i.e., the possibility of low throughput and higher cost).

In recent years, the issue of improving the effective pinning of magnetic flux lines in HTS films has been successfully addressed by many groups through manipulation of defects in a REBCO film matrix by doping. That is, through various methods of deposition-controlled nanostructural engineering, additional pinning centers of different sizes and morphologies, in addition to the existing naturally formed growth-induced defects, have been introduced into REBCO films. One particularly successful and heavily studied dopant is BaZrO₃ (BZO), first incorporated into the YBCO films in the form of 5-100 nm size particles by pulsed laser deposition (PLD). This was followed by the demonstration of strain-induced formation of columnar defects, comprising self-assembled nanodots and/or nanorods of BZO within the superconducting matrix. Similar columnar defects were also observed by incorporation of yttria-stabilized zirconia (YSZ) in REBCO films. The columnar defects have proven to be very effective for enhancing the pinning performance, especially for fields applied nearly parallel to the c-axis of the REBCO film. Creation of such columnar defects has recently been shown possible using the scalable and economically tenable technique of metal-organic chemical vapor deposition (MOCVD). Enhanced flux pinning in MOCVD-YBCO films through Zr additions has been described in “Enhanced flux pinning in MOCVD-YBCO films through Zr additions: systematic feasibility studies,” Aytug et al, Supercond. Sci. Technol. 23 (2010) 014005. The disclosure of this document is hereby incorporated fully by reference. To realize self-assembly of BZO nanodots into columnar defects within the MOCVD REBCO films, growth rates had to be reduced more than 50% and deposition temperatures had to be significantly increased above the normal growth temperatures. Also, Zr doping can result in reduced superconducting transition temperature (T_{c}) and J_{c} performance, and has offered only limited pinning improvement for fields applied near the a-b axis of the REBCO film at 5-77 K.

### SUMMARY OF THE INVENTION

A method of making a superconducting article includes the steps of providing a substrate having an uniaxially or biaxially textured surface; and using MOCVD to deposit onto the surface an epitaxial layer of material comprising REBCO and a secondary phase comprising a dopant. The dopant comprises at least one element selected from the group consisting of Nb, Ta and V, and combinations thereof.

The method can include the step of providing a precursor solution comprising precursor compounds for RE, Ba, Cu and the dopant. The precursor compound can be selected from the group consisting of tris(2,2,6,6-tetramethyl-3,5-heptanedionato)yttrium; bis(2,2,6,6-tetramethyl-3,5-heptanedionato)barium phenanthroline adduct; bis(2,2,6,6-tetramethyl-3,5-heptanedionato)copper; tetrakis(2,2,6,6-tetramethyl-3,5-heptanedionato)niobium; and combinations thereof. The precursor compound can also be selected from the group consisting of Pentakis (dimethylamino)tantalum(V); Cyclopentadienylniobium(V) tetrachloride; Niobium(V) ethoxide; Niobium(IV) 2-ethylhexanoate; Pentakis(dimethylamino)niobium(V); Tetrachlorobis(tetrahydrofuran)niobium(IV); t-Butylimidotris(dimethylamido)tantalum(V); Pentakis(dimethylamino)tantalum(V); Pentamethylcyclopentadienyltantalum tetrachloride; Tantalum(V) methoxide; Tantalum(V) tetraethoxyacetylacetonate; Tantalum(V) (tetraethoxy); Vanadium(III) acetylacetonate; Vanadyl naphthenate; and Cyclopentadienylvanadium tetracarbonyl; and combinations thereof. The precursor compound is dissolved in a suitable solvent such as tetrahydrofuran.

The RE can be Y and the stoichiometry of Y(RE), Ba and Cu in the precursor solution can be Y_{1±0.5}, Ba_{2±0.5}, Cu_{3±0.5}. The secondary phase can comprise at least one of YₚBa_{q}NbᵣOₛ, where p=1±0.5, q=2±0.5, r=1±0.5, and s=6±0.5, such as YBa₂NbO₆, and BaₓNb_{y}O_{z}, where x=0-14.66, y=1-17, and z=3−32. The secondary phase can comprise at least one of YBa₂TaO₆, BaₓTa_{y}O_{z}, where x=0-7, y=1-6, z=1-16, YₓTa_{y}O_{z} where x=1-10, y=1-7, z=3-25, and Ba(Y_{0.5}Ta_{0.5})O₃. The secondary phase can comprise at least one of YBa₂VO₆, YBa₂V₃O₁₁, BaₓV_{y}O_{z}, where x=0-8, y=1-12, z=0.2-30, and YₓV_{y}O_{z} where x=1-10, y=1-2, and z=4-20. Combinations of these secondary phase compounds are also possible. The Nb content can be between 0.1 mol % and 50 mol %, or between 0.1 mol % and 10 mol %, with respect to the moles of REBCO. The secondary phase can be a double perovskite.

The MOCVD process can include vaporizing a precursor solution, and mixing vapor from the precursor solution with oxygen. The oxygen flow rate of the mixing step can be between 1.1-1.7 liter/min, or between about 1.1-1.2 liters/min. The deposition pressure of the MOCVD can be between 1-5 Torr, or between 2-3 Torr. The deposition temperature of the MOCVD can be between about 920-975° C., or between about 850-980° C. The precursor delivery rate of the MOCVD can be between about 1-10 muter/min, or between about 1-3 muter/min, and can be between about 1-1.15 muter/min. The deposition rate of the MOCVD can be between about 0.01-2.0 micron/min. The deposition rate of the MOCVD can be between about 0.2-0.3 micron/min.

The substrate can comprise at least one of component selected from the group consisting of stainless steel, Cu, Ni, Fe, Al, Ag, and alloys of any of the foregoing. The substrate can comprise at least one of the group consisting of Ni—W, Ni—Cr, Ni—Cr—W, Ni—Cr—V, Ni—V, and Ni—Mn. The substrate can comprise at least one of the group consisting of MgO, SrTiO₃, and REAlO₃, where RE comprises at least one rare-earth element.

A superconducting article can be produced by the process of providing a substrate having a uniaxially or biaxially textured surface; and using MOCVD to deposit onto the surface an epitaxial layer of material comprising REBCO and a secondary phase comprising a dopant. The dopant comprises at least one element selected from the group consisting of Nb, Ta and V.

### BRIEF DESCRIPTION OF THE DRAWINGS

There are shown in the drawings embodiments which are presently preferred it being understood, however, that the invention is not limited to precise arrangements and instrumentalities, shown, wherein:

FIG. 1 is a schematic diagram of a MOCVD system and process.

FIGS. 2A-B are plots of J_{c} vs. B (Tesla) and Fₚ (GN/m³) vs. B(Tesla) for both Nb doped and undoped YBCO.

FIG. 3 is a plot of J_{c} (A/cm²) vs. angle (degrees) for doped (Nb and Zr) and undoped YBCO at 1 Tesla applied field and 77 K.

FIGS. 4A-C are cross-sectional transmission electron microscopy (TEM) and FIGS. 4D-E FIB-scanning electron microscopy (SEM) views of Nb-doped (2.5 mol % and 5 mol %) YBCO films.

FIGS. 5A-C show a Z-contrast scanning TEM image (FIG. 5A) and high resolution energy dispersive spectroscopy (EDS) line scans (FIGS. 5B-C) of a Nb-doped YBCO film. FIG. 5B shows the EDS signals across a columnar defect and FIG. 5C displays signals across a compositionally stoichiometric YBCO matrix region.

FIGS. 6A-B are a plot of intensity (arbitrary units, a.u.) vs. 2θ (degs.) and particle size (nm) vs. Nb-content (mol %), respectively.

FIG. 7 is a plot of normalized absorption vs, x-ray energy (eV) for Nb-doped films.

FIG. 8 is a plot of Fourier transform magnitude(Å⁻³) vs. radial coordinate, r (Å), for 10 mol % Nb, Fit (60% BaNb₂O₆+40% YBa₂NbO₆), and YBa₂NbO₆.

FIGS. 9A-B are a plot of T_{c} vs. Nb-concentration (mol %) and a plot of J_{c} vs. Nb-concentration (mol %), respectively.

FIGS. 10A-B are plan view SEM images of Nb-doped YBCO films, depicting grain content and structural changes with increasing Nb content.

FIGS. 11A-B are a plot of perovskite (YBa₂NbO₆) vol % vs. Nb concentration (mol %) and a plot of YBCO vol % vs. Nb concentration (mol %), respectively.

FIGS. 12A-H are elemental spectral images showing Y—Ba—Nb—O columnar defects and Y₂O₃ & Y—Ba—Nb—O planar defects.

FIGS. 13A-E are schematic diagrams depicting A) Standard undoped REBCO/LaMnO₃/IBAD(Ion Beam Assisted Deposition)-MgO architecture; B) Nb-doped REBCO/LaMnO₃/IBAD-MgO architecture, representing columnar defect structures; C) Nb-doped REBCO/LaMnO₃/IBAD-MgO architecture, representing planar defect structures; D) Nb-doped hybrid REBCO/LaMnO₃/IBAD-MgO architecture; E) Nb-doped REBCO/LaMnO₃/IBAD-MgO architecture, representing defect structures with angular splay.

For a better understanding of the present invention, together with other and further objects, advantages and capabilities thereof, reference is made to the following disclosure and appended claims in connection with the above-described drawings.

### DETAILED DESCRIPTION OF THE INVENTION

The present invention provides for the creation of pinning defects in superconducting films through the introduction of niobium (Nb), Tantalum (Ta) and/or Vanadium (V) compounds into the superconductor film during a MOCVD process. The defects are incorporated into the superconductor film as a secondary phase. This phase can be constituted by a perovskite or double perovskite or perovskite-like structure including the dopant. In the case of Nb, the secondary phase can comprise one or both of YₚBa_{q}NbᵣOₛ, where p=1±0.5, q=2±0.5, r=1±0.5, and s=6±0.5, such as YBa₂NbO₆, and BaₓNb_{y}O_{z}, where x=0-14.66, y=1-17, and z=3-32. In the case of Ta, the secondary phase can comprise one or both of YBa₂TaO₆ and BaₓTa_{y}O_{z}, where x=0-7, y=1-6, z=1-16, and YₓTa_{y}O_{z} where x=1-10, y=1-7, z=3-25, and Ba(Y_{0.5}Ta_{0.5})O₃. In the case of V, the secondary phase can comprise one or some combination of YBa₂VO₆, YBa₂V₃O₁₁, and BaₓV_{y}O_{z}, where x=0-8, y=1-12, z=0.2-30, and YₓV_{y}O_{z} where x=1-10, y=1-2, and z=4-20. Combinations of Nb, Ta, and V secondary phase compounds are also possible.

The oxide superconductor layer can be REBa₂Cu₃O₇ where RE is a rare earth element. The invention can be utilized with different REBCO superconductors, and variations in stoichiometry from REBa₂Cu₃O₇ are possible. RE comprises at least one rare-earth element, namely Y, La, Ce, Pr, Nd, Pm, Sm, Eu, Gd, Th, Dy, Ho, Er, Tm, Yb, and Lu. The invention can also be utilized with other copper oxide based superconductors, such as La_{1.85}Ba_{0.15}CuO₄, Nd_{1.85}Ce_{0.15}CuO₄, (Bi, Pb)₂Sr₂CaCu₂O₈, (Bi, Pb)₂Sr₂Ca₂Cu₃O₁₀, HgBa₂Ca₂Cu₃O₁₀, Tl₂Ba₂Ca₂Cu₃O₁₀, HgBa₂CaCu₂O₈, and HgBa₂Ca₂Cu₃O₁₀.

The Nb/Ta/V defects provide improved pinning properties comparable to Zr-modified films through self assembly without sacrificing deposition parameters. It is believed, without limiting the invention and without being necessary to practice the invention, that Nb provides performance improvements for MOCVD REBCO films because it may form various secondary phases through reaction with Ba and Y within the YBCO matrix. Some variants of such phases include cubic perovskite, BaNbO₃ and perovskite-like BaNb₅O₈, BaNb₄O₆, Ba₂Nb₅O₉, monoclinic YNbO₄, and pyrochlore Y₃NbO₇. In addition, Y and Ba in the REBCO matrix may also react with Nb to form perovskite and/or perovskite-like compounds, such as YBa₂NbO₆. Similar phases can be obtained with Ta and V.

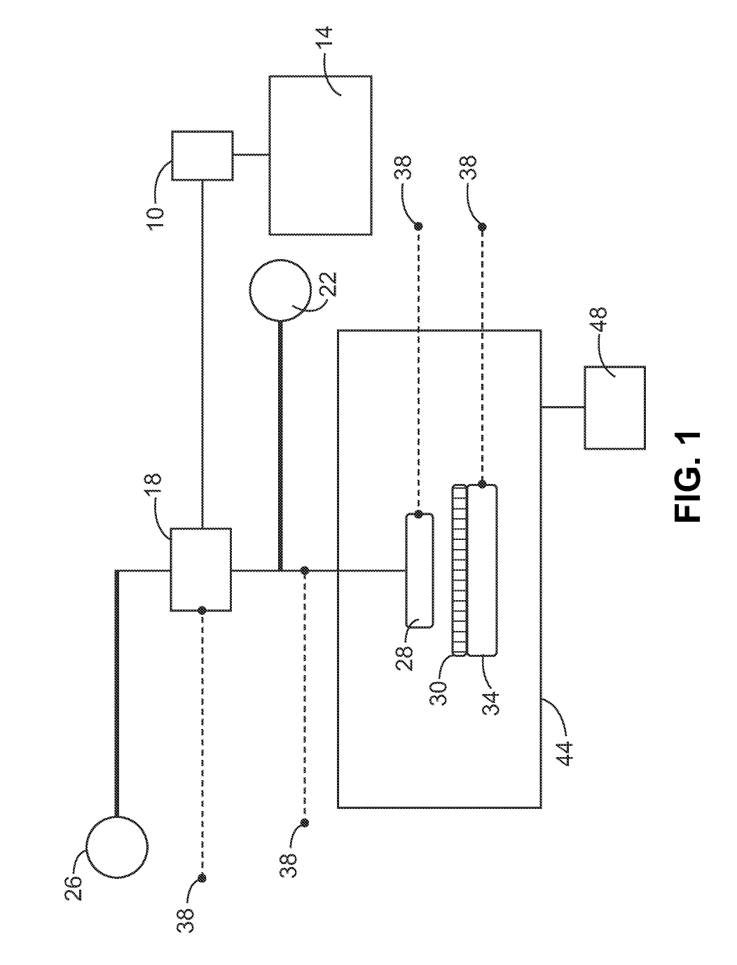

In FIG. 1 there is shown a system suitable for carrying out the process of the invention. A liquid precursor delivery pump 10 directs the liquid precursor from source 14 to a vaporizer 18. A carrier gas such as argon from source 26 is also directed to the vaporizer 18. Oxygen from an oxygen source 22 is mixed with the carrier/precursor gas mixture. The O₂/argon/precursor mixture is then passed through a spray head 28 where it contacts the substrate 30. The substrate 30 is heated by a substrate heater 34, which can heat the substrate 30 by conduction, convection, or any other suitable method or combination thereof. Suitable sensors and controls, such as thermocouples 38, and valves and other process components can also be included, particularly where sizing for industrial production. The deposition process takes place in a suitable reaction chamber 44, and a vacuum pump 48 can be provided to maintain the reaction chamber 44 at a suitable vacuum for the process. Industrial MOCVD systems and equipment are available, and many such systems and equipment could be utilized with the invention.

The precursor solutions can be any precursor suitable for MOCVD and the reactant components of the invention (eg., Y, Ba, Cu, Nb, Ta, V). In one aspect, the MOCVD was carried out using tris(2,2,6,6-tetramethyl-3,5-heptanedionato)yttrium (39-100, Columbia Materials, Vancouver Wash.); bis(2,2,6,6-tetramethyl-3,5-heptanedionato)barium phenanthroline adduct (56-100, Columbia Materials, Vancouver Wash.); bis(2,2,6,6-tetramethyl-3,5-heptanedionato)copper (29-100 Columbia Materials, Vancouver Wash.); tetrakis(2,2,6,6-tetramethyl-3,5-heptanedionato)niobium (IV), 99% Nb(TMHD)₄ (41-7000 Strem Chemicals, Newburyport Mass.). A suitable Ta precursor is Pentakis(dimethylamino)tantalum(V). Other precursor solutions used in MOCVD which have utility for the invention include Cyclopentadienylniobium(V) tetrachloride, 98% (41-0500 Strem Chemicals, Newburyport Mass.); Niobium(V) ethoxide (99.9+%-Nb) (93-4104 Strem Chemicals, Newburyport Mass.); Niobium(IV) 2-ethylhexanoate (41-1260 Strem Chemicals, Newburyport Mass.); Pentakis(dimethylamino)niobium(V), 99% (41-5300 Strem Chemicals, Newburyport Mass.); Tetrachlorobis(tetrahydrofuran)niobium(IV) (41-6500 Strem Chemicals, Newburyport Mass.); t-Butylimidotris(dimethylamido)tantalum(V), min. 98% (73-0700 Strem Chemicals, Newburyport Mass.); Pentakis(dimethylamino)tantalum(V), 99% (73-0800 Strem Chemicals, Newburyport Mass.); Pentamethylcyclopentadienyltantalum tetrachloride, 98% (73-0900 Strem Chemicals, Newburyport Mass.); Tantalum(V) methoxide (99.99+%-Ta) PURATREM (93-7329 Strem Chemicals, Newburyport Mass.); (73-0700 Strem Chemicals, Newburyport Mass.); Tantalum(V) tetraethoxyacetylacetonate (99.99+%-Ta) PURATREM (73-5000 Strem. Chemicals, Newburyport Mass.); Tantalum(V) (tetraethoxy)[BREW] (99.99+%-Ta) PURATREM (73-7373 Strem Chemicals, Newburyport Mass.). Possible vanadium precursors are: Vanadium(III) acetylacetonate. 98% (23-2250 Strem Chemicals, Newburyport Mass.): Vanadyl naphthenate, 35% in naphthenic acid (2.8-3.2% V) (23-4400 Strem Chemicals, Newburyport Mass.); Cyclopentadienylvanadium tetracarbonyl, min. 97% (23-0350 Strem Chemicals, Newburyport Mass.). Other precursor compounds are possible.

The precursor compounds can be obtained as crystalline (solid) powders and dissolved in a suitable solvent. One such suitable solvent is THF (tetrahydrofuran) although other solvents are possible. All of these compounds can be dissolved in the solvent and the solution total molarity is adjusted to 0.3 molar. Precursor molarity can be between 0.1-1 molar, or can have a lower limit and an upper limit anywhere within this range. The precursor solutions are delivered in proportion to the mole ratio of the constituents in the final product. To make a YBCO film this solution includes Y, Ba and Cu, and the precursors can be mixed in the following stoichiometry: Y_{1±0.5}, Ba_{2±0.55}, Cu_{3±0.8}, or Y_{1±0.25}Ba_{2±0.25}Cu_{3±0.4}, and accordingly their corresponding powder weight is calculated before adding into the THF solution. In one embodiment the Y—Ba—Cu stoichiometry is about Y_{1.3}Ba₂Cu_{2.6}. The Nb content is varied between 0.1 mol % to 10 mmol %. This is calculated with respect to moles of YBCO or the REBCO that is being formed. The best result in terms of T_{c} and J_{c} was obtained with 5 mol % Nb doped sample. The range of Nb doping could be from 0.01 mol % to 50 mol %, and the range can have a lower limit and an upper limit anywhere within this range, such as at any 0.01 mol % increment within this range. In one aspect, the lower limit can be 1, 2, 3, 4, 5, 10, 15, 20, 25, 30, or 35 mol %, and the upper limit can be 50, 45, 40, 35, 30, 25, 20 or 15 mol %.

The precursor solutions are vaporized and mixed with oxygen. The mixture is carried by an inert gas such as argon gas, at oxygen flow rates between 1.1-1.7 liter/min. An oxygen flow rate between around 1.1-1.2 liter/min produced films with better T_{c} and J_{c} values. The conditions that can be employed for the MOCVD deposition can vary. The deposition pressure can be between 1-5 Torr, or between 2-3 Torr, and in one embodiment is about 2.5 Torr. The deposition temperature (substrate temperature or as an approximation the heater temperature) can be between about 920-975° C., or 945-955° C., or 850-980° C. or could have any lower limit within this range and upper limit within this range and above the lower limit. In one embodiment the deposition temperature is about 950° C. The HTS precursor (all) delivery rate for the combined Y, Ba, Cu, and Nb (and/or Ta, V) precursor solutions is between about 1-3 ml/min, and 1-10 ml/min, and in one embodiment is between about 1-1.15 ml/min. The tape speed of the substrate is in one embodiment about 150 cm/hr, and can be between about 1 cm/hr-1000 m/hr. The deposition rate in one embodiment is about 0.24 micron/min, and can range between about 0.01-2.0 micron/min, or between about 0.2-0.3 micron/min.

The sizes of the deposited defects can be between 12-18 nm, or can be between 10-25 nm, 2-50 nm, 2-100 nm, or 2-1000 nm, or can have a lower limit and an upper limit anywhere within this range and above the upper limit. The spacing between defects within the film can be between 2-25 nm, 2-50 nm, or 2 nm-100 nm, or can have a lower limit and an upper limit anywhere within this range. The concentration of the defects, based on the total volume, moles, or weight of the superconductor film, can be between 0.2% for 1.25 mol % Nb, to 20% for 10 mol % Nb, and can have a lower limit and an upper limit anywhere within these ranges. The defect density can be controlled by controlling the doping amount. The Nb can be combined with other dopants, such as Zr, Ce, Ho, Eu, Er, Sm, Ta, Sn, and V, either alone or in combination. The splay of the defects can be controlled by temperature, deposition rate, and deposition pressure.

The defects can be in the form of particulates or nanodots, columns of nanodots, or nanocolumns, or in any combination of these forms. The defects can be oriented along the t-axis, or along the a-b planes, or can be splayed at an angle between the c-axis and the a-b planes, or in any combination of these orientations. The various reaction conditions including reactants, reactant concentrations, reactant flow rates, deposition temperatures and pressures, substrate temperature, and deposition rate can be modified to change the shape, size and distribution of the defects.

The defects that are obtained can be, in the case of Nb deposition, any of several Nb—O containing compounds. These include compounds, in addition to or in place of YBa₂NbO₆, such as BaₓNb_{y}O_{z} and Nb_{y}O_{z}. Such Nb—O compounds include BaNb₂O₆, Ba₂Nb₅O₉, Ba(Nb₈O₁₄), Ba(Nb₃O₆), Ba(NbO₃), Ba₂Nb₅O₉, BaNb₂O₆, Ba_{0.8}Nb₅O₈, NbO, NbO₂, Nb₂O₅, Y₃NbO₇, and YNbO₄. Similar Ta and V compounds are also possible with Ta and V doping. Double perovskites have been found to provide good pinning characteristics.

A superconductor such as REBCO including the Nb/Ta/V defects of the invention is supported on or deposited on a suitable substrate. Suitable substrate materials include, but are not limited to stainless steel, Cu, Ni, Fe, Al, Ag, and alloys of any of the foregoing. Suitable substrate alloying elements include, but are not limited to W, Cr, V, and Mn. Suitable substrate alloys include, but are not limited to Ni—W, Ni—Cr, Ni—Cr—W, Ni—Cr—V, Ni—V, and Ni—Mn. Suitable oxide substrates include, but are not limited to MgO, SrTiO₃, and REAlO₃, where RE comprises at least one rare-earth element, namely Y, La, Ce, Pr, Nd, Pm, Sm, Eu, Gd, Tb, Dy, Ho, Er, Tm, Yb, and Lu. As used herein, “supported on” refers to a layer that is above another layer, while “deposited on” refers to a layer that is above and in physical contact with another layer.

The term “epitaxial” is used herein and understood by those skilled in the art to mean the growth (method) and placement (apparatus) of a crystalline substance on a crystalline substrate, where the crystalline substance formed follows the crystallographic orientation of the crystalline substrate. Epitaxial crystal growth advantageously permits the formation of crystallographic layers having a high level of crystallographic correlation with respect to an underlying crystalline substrate layer, permitting the formation of improved devices.

Biaxial texture refers to {100}<100> crystallographic orientations both parallel and perpendicular to the basal plane of a material. The biaxially textured second buffer film can be aligned along a first axis along the [001] crystal direction, and along a second axis having a crystal direction selected from the group consisting of [111], [101], [113], [100], and [010]. A biaxially textured layer can also be defined as a polycrystalline material in which both the crystallographic in-plane and out-of-plane grain-to-grain misorientation of the topmost layer is less than about 30 degrees, such as less than about 20 degrees, 15 degrees, 10 degrees, or 5 degrees, but is generally finite typically greater than about 1 degree. The degree of biaxial texture can be described by specifying the distribution of grain in-plane and out-of-plane orientations as determined by x-ray diffraction. A full-width-half-maximum (FWHM) of the rocking curve of the out-of-plane (Δθ) and in-plane (ΔΦ) reflection can be determined. Therefore, the degree of biaxial texture can be defined by specifying the range of Δθ and ΔΦ for a given sample. Other suitable definitions have also been set forth in varying terms. For the purpose of the description of the present invention, biaxial texture is construed to include single-crystal morphology.

According to the invention, the metal material can be annealed in a reducing atmosphere to develop biaxial texture. This can be accomplished by annealing in a vacuum at a predetermined pressure. The pressure may be any suitable pressure, and is preferably lower than approximately 5×10⁻⁶ Torr, and optimally less than approximately 2×10⁻⁶ Torr. During vacuum annealing, the metal material is enclosed in an envelope formed from a material which attracts oxygen, such as tantalum. For Ni and Ni-based alloys, annealing can occur at a temperature range of between approximately 600° C. and approximately 1100° C. Preferably, however, annealing occurs between approximately 800° C. and approximately 1000° C., and ideally occurs at 1000° C. For Cu and Cu-based alloys, annealing can occur at a temperature range of between approximately 400° C. and approximately 1000° C. Preferably, however, annealing occurs between approximately 500° C. and approximately 900° C. Annealing may continue for any appropriate amount of time, and preferably occurs for approximately 60 minutes.

After rolling and annealing, a biaxially-textured metal substrate is formed upon which epitaxial layers may be grown. Although the biaxially-textured metal substrate can be any metal or metal alloy upon which an epitaxial layer may be grown, the metal substrate is preferably composed of biaxially-textured Cu, Cu alloy, Co, Mo, Cd, Pd, Pt, Ag, Al, Ni, or Ni alloy. If the metal substrate is a Cu or Ni alloy, any Cu or Ni alloy upon which an epitaxial layer can be grown is acceptable. Preferably, the Ni is alloyed with Cr, Mo, V, Co, Cu, or a rare earth element. These materials are generally preferred for most applications because they tend to reduce ferromagnetism.

The starting purity of the metal substrate is preferably at least 99.9%, and in a preferred embodiment is greater than 99.99%. The degree of biaxial texture in the metal substrate, specified by the FWHM of the out-of-plane and in-plane diffraction peak, is typically greater than 2° and less than 20°, preferably less than 15°, and optimally less than 10°.

An alternative method of forming a biaxially-textured metal surface is by ion-beam assisted deposition. With this technique, a metal film is deposited by a vacuum deposition technique in the presence of an energetic ion beam. The energetic ions induce a preferred crystallographic texture in the depositing film. For (001) textured cubic materials such as Ni, an ion beam directed at an angle of approximately 45° or 54° can induce in-plane texture. These angles correspond to the (100) and (111) directions of a cube oriented with its (100) direction perpendicular to the metal surface. In this case, the metal surface is preferably composed of Cu, Cu-based alloys, Ni, Ni-based alloys, Ag, Al, Pt, Pd, Cd, Mo, or Co. IBAD processes are described in U.S. Pat. Nos. 6,632,539, 6,214,772, 5,650,378, 5,872,080, 5,432,151 and 6,361,598; ISO processes are described in U.S. Pat. Nos. 6,190,752 and 6,265,353. The disclosure of all of these patents is incorporated herein by reference. Standard LMO/IBAD-MgO templates were used in tests of this invention, but any architecture wherein the Nb/Ta/V-doped REBa₂Cu₃O₇ film is supported by a substrate can be made and are therefore included in the present invention. It is understood that, instead of having a biaxial texture, the metal surface can be crystalline with a single uni-axial orientation, or polycrystalline with arbitrary grain-to-grain orientation, depending on the intended application. In both cases, the crystallographic orientation of the epitaxial layer will be approximately that of the immediate metal surface.

A buffer system generally comprises the layers between the substrate and the superconductor layer. Buffer systems in accordance with the present invention can comprise any known architecture, and can be deposited by any known means. Some examples of suitable deposition methods include, but are not limited to: physical vapor deposition (PVD) which includes pulsed laser deposition (PLD), electron beam evaporation, sputtering (reactive, rf, dc, for example), etc.; chemical vapor deposition (CVD) which includes metal-organic CVD (MOCVD), solgel deposition, metal-organic deposition, spray pyrolysis, and plasma spray; and plating methods such as electrodeposition and electroless deposition.

Some examples of suitable buffer layers include, but are not limited to TiN, CeO₂, Y₂O₃, SrTiO₃, BaZrO₃, BaSnO₃, BaCeO₃, YSZ, (RE₁₋ₓSrₓ)MnO₃, REMnO₃, RE₂O₃, REAlO₃, RE₂Zr₂O₇, RE₃NbO₇, RESMO, and REMO where RE comprises at least one rare-earth element, namely Y, La, Ce, Pr, Nd, Pm, Sm, Eu, Gd, Th, Dy, Ho, Er, Tm, Yb, and Lu, and where M comprises at least one metal. Some specific examples of suitable conductive buffer layers are LaNiO₃, LaO₇, CaO₃, MnO₃, LaCoO₃, LaO₅, SrO₅, TiO₃, SrRuO₃, and La₂CuO₄.

The MOCVD process of the invention can be carried out using equipment and methods suitable for this purpose. One such system is described in Selvamanickam, V., 2001 High-current Y—Ba—Cu—O coated conductor using metal organic chemical-vapor deposition and ion-beam-assisted deposition, IEEE Trans. Appl. Supercond. 11 3379. The use of MOCVD to deposit YBCO films is described in Deposition studies and coordinated characterization of MOCVD YBCO films on IBAD-MgO templates; Aytug et al., Supercond. Sci. Technol. 22 (2009) 015008. The disclosure of these references is fully incorporated by reference.

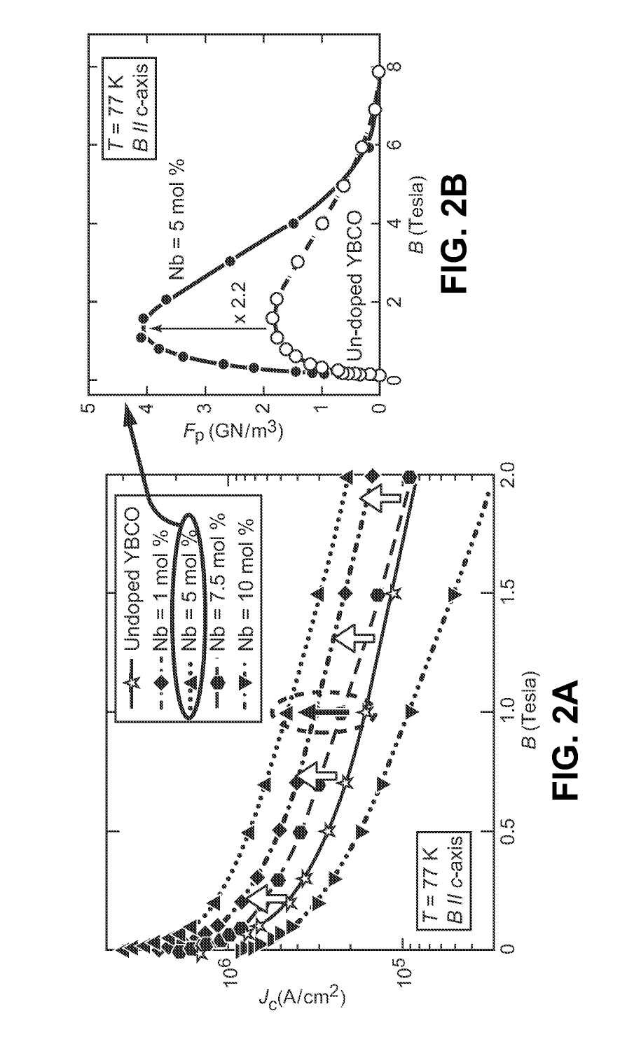

FIGS. 2A-B are plots of J_{c} vs. B (Tesla) and Fₚ (GN/m³) vs. B(Tesla) for both Nb doped and undoped YBCO. FIG. 2 demonstrates the effect of increasing Nb-content on in-field performance of J_{c} in MOCVD-YBCO (0.4 μm) systems. For Nb=1 and 5 mol %, there is enhanced J_{c} performance over a wide range of fields. The improvement for 5% Nb is significant—the J_{c} improves ˜150% at 1 T when compared to undoped YBCO. The pinning strength (F_{p,max}) is increased by a factor of ˜2 with Nb (5 mol %) modifications. As the doping level increases above 5 mol % improvement in field dependence of J_{c} decreases.

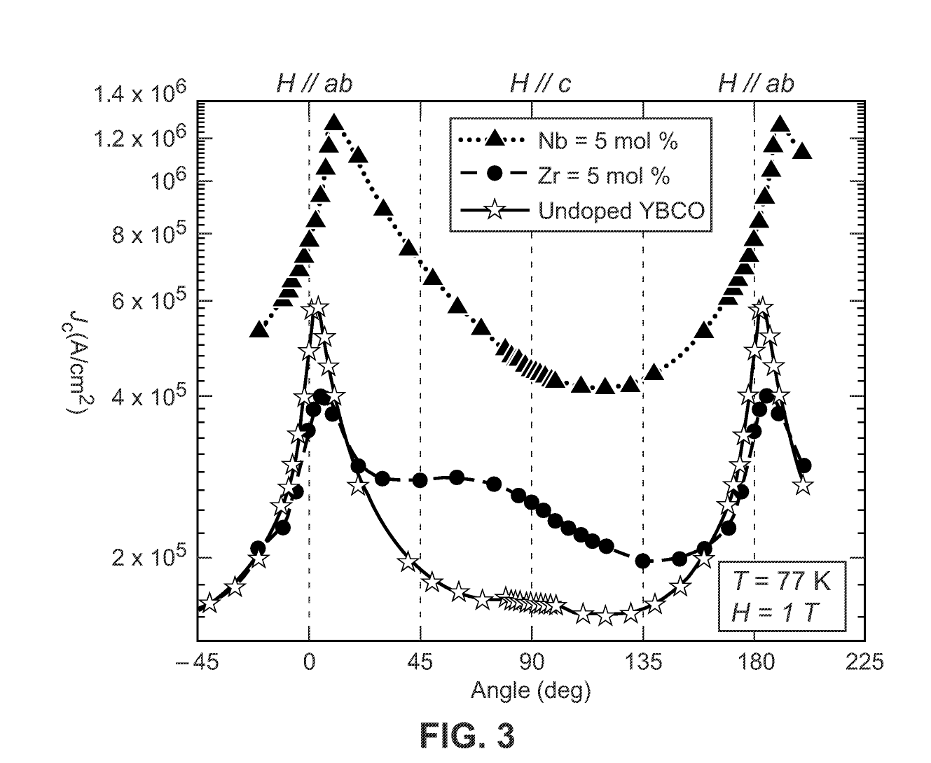

FIG. 3 is a plot of J_{c} (A/cm²) vs angle (degrees) for Nb doped (5 mmol %) YBCO, Zr doped (5 mol %) YBCO, and undoped YBCO. FIG. 3 illustrates that for the Nb doped YBCO, significant enhancement in J_{c} is obtained over a wide range of angles. Performance with respect to YBCO is improved ˜150% along the B//c-axis and about ˜120% along the B//ab-planes. The minimum J_{c,min} is improved ˜160%. No indication of directional pinning behavior is found—there is observed a relatively isotropic pinning dependence. The Zr doped YBCO has significantly lower values both along the Bile-axis and along the B//ab-planes, as compared to the Nb doped sample under the process conditions defined herein.

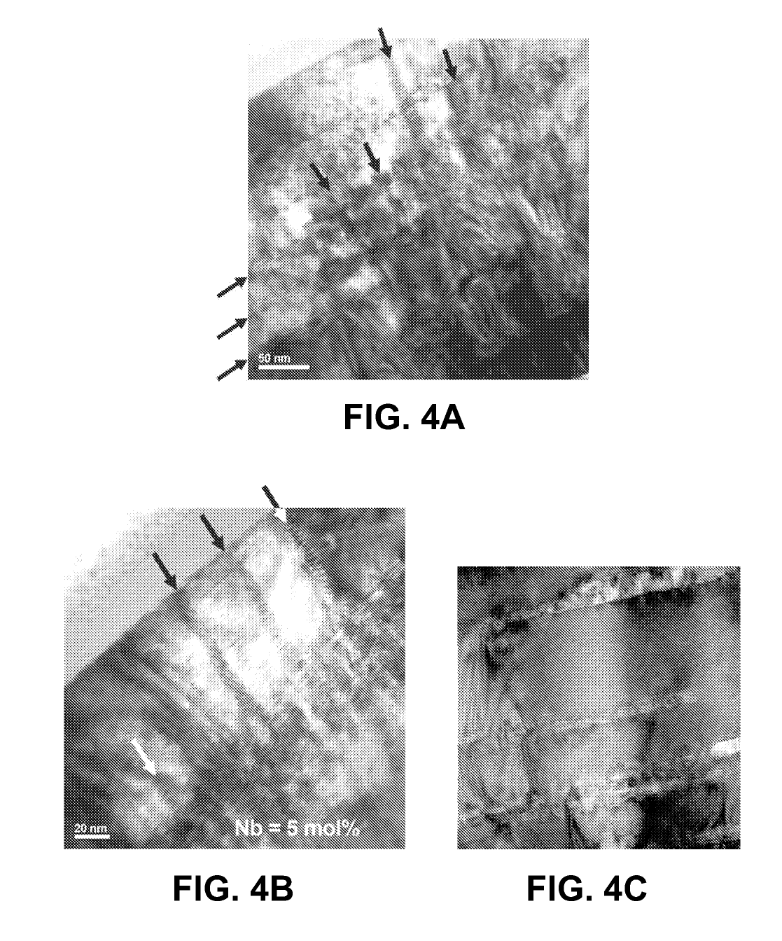

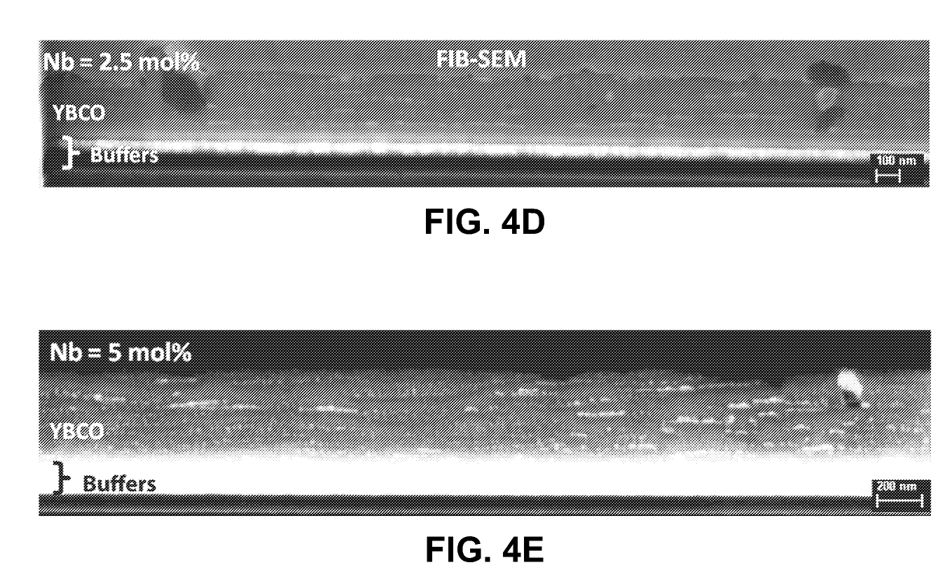

FIGS. 4A-C are cross-section TEM views and FIGS. 4D-E FIB-SEM views of Nb-doped (2.5 mol % and 5 mol %) YBCO. In FIGS. 4A and 4B (5 mol % Nb) there are both columnar defects and planar defects. In FIG. 4C (2.5 mol % Nb) there are both columnar and planar defects. In FIG. 4D and in FIG. 4E (5 mol % Nb) there are many strings of precipitates //ab-planes. In addition there are (5 mol % and 2.5 mol % Nb) there are many small RE-oxide particles distributed throughout the YBCO film matrix. The observation of columnar and planar defects induced by a single dopant element (Nb in this case) is a significant aspect of this invention.

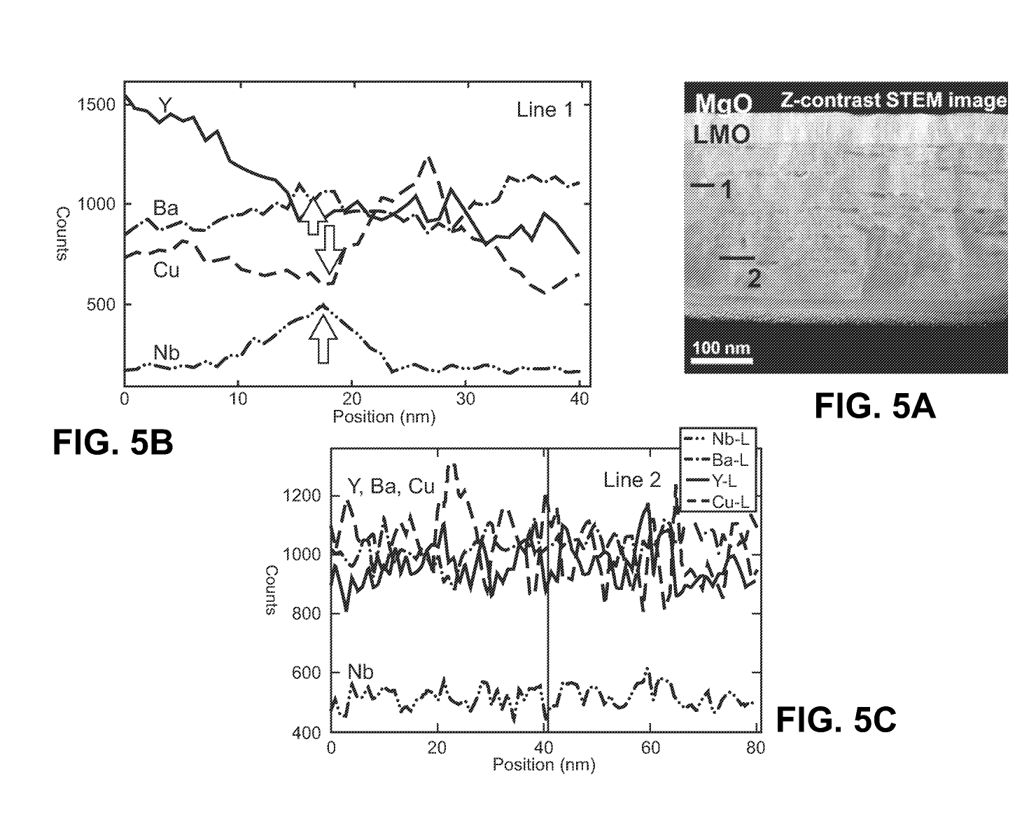

FIGS. 5A-C shows a Z-contrast STEM image (FIG. 5A) and high resolution EDS line scans (FIGS. 5B-C). The high resolution energy dispersive x-ray spectroscopy (EDS) line scans provide evidence that the columnar defects contain Nb. Across the columnar defect the Nb signal is enhanced, the Ba signal is enhanced, and the Cu signal is suppressed. This is consistent with a Y—Ba—Nb containing material. The matrix is stoichiometric REBCO.

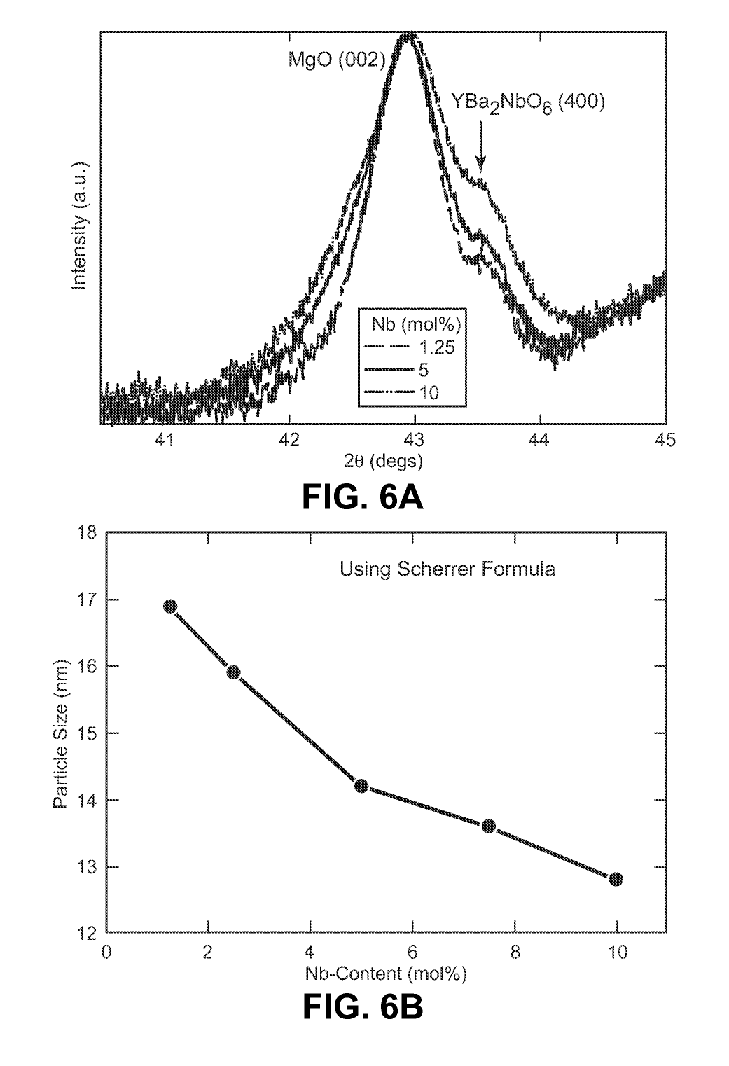

FIGS. 6A-B are a plot of intensity (a.u.) vs. 2θ (degs.) and a plot of particle size (nm) vs. Nb-content (mol %). FIG. 6 illustrates that YBa₂NbO₆ grows heteroepitaxially with YBCO (2θ scan). Using the Scherrer equation, it was determined that YBa₂NbO₆ particle size decreases with doping.

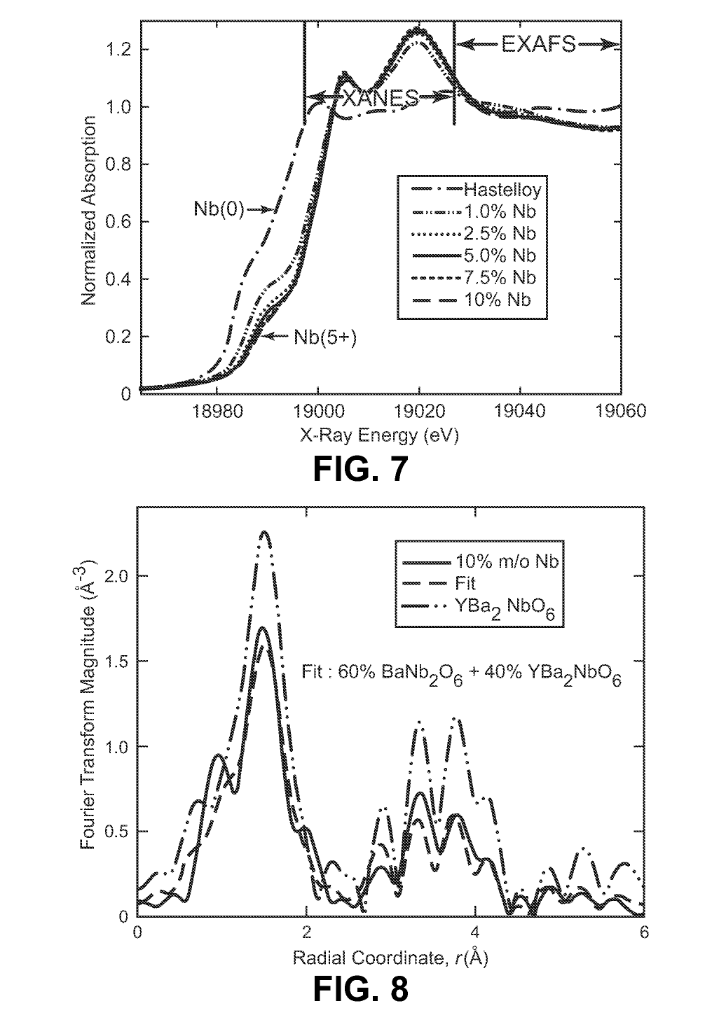

FIG. 7 illustrates the results of X-ray absorption spectroscopy (XAS) scans of the Nb-doped films, including x-ray absorption near-edge structure (XANES) and extended x-ray absorption fine structure (EXAFS). FIG. 7 is a plot of normalized absorption vs. x-ray energy (eV) for Nb-doped films (Hastelloy, 1.0%, 2.5%, 5%, 7.5%, 10%). FIG. 7 suggests the presence of a second Nb—Ba—O phase. The presence of Nb(0) in the Hastelloy substrate is seen, along with the effect of this Nb reduced by glancing angle XAS. FIG. 7 also illustrates that the majority of Nb added to YBCO is in the +5 valence state.

FIG. 8 is a plot of Fourier transform magnitude (Å⁻³) vs. radial coordinate, r (Å), for 10 mol % Nb, Fit (60% BaNb₂O₆+40% YBa₂NbO₆), and YBa₂NbO₆. FIG. 8 is a graph of X-ray absorption spectroscopy of the Nb-doped films and suggests the presence of a second Nb—Ba—O phase. EXAFS fitting best matches with respect to radial coordinates and coordination numbers a mix of YBa₂NbO₆ and a second Ba—Nb—O phase, such as BaNb₂O₆.

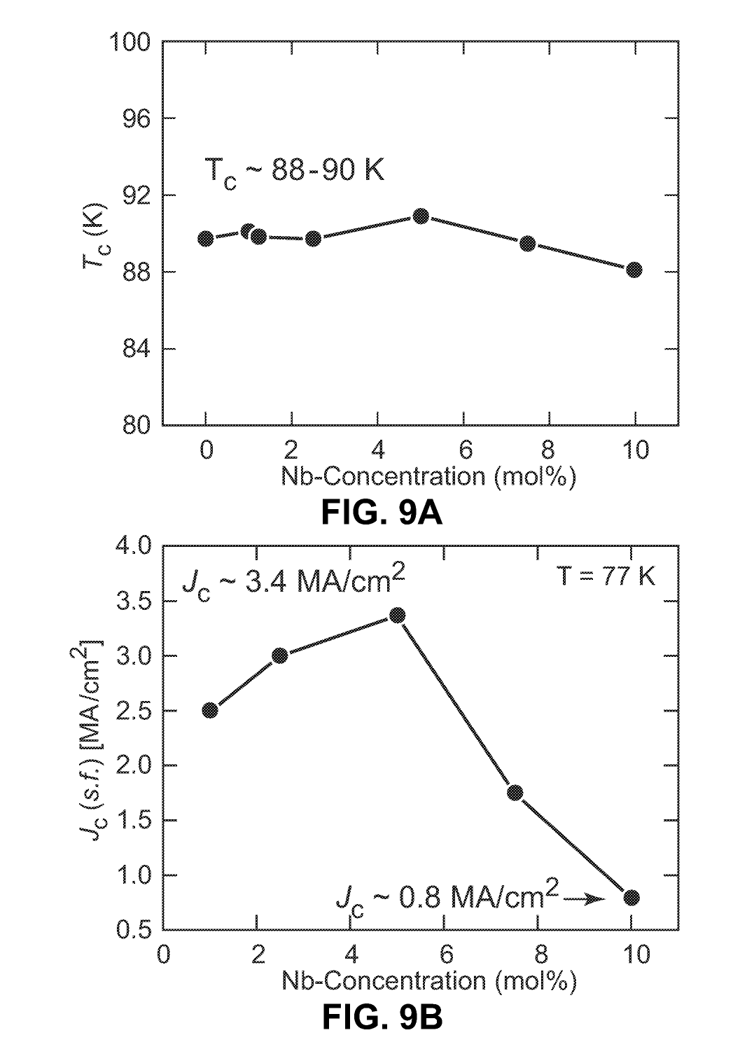

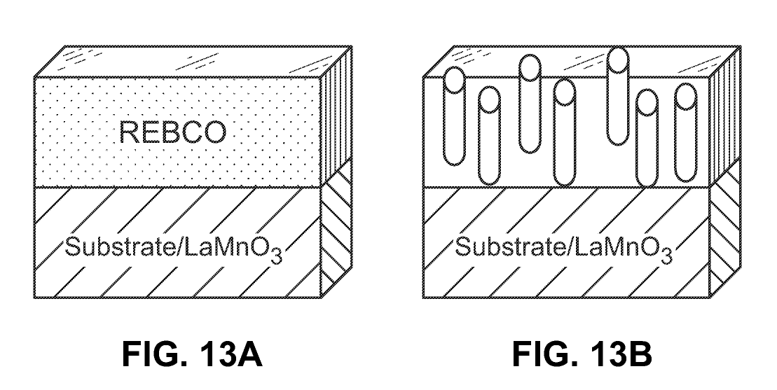

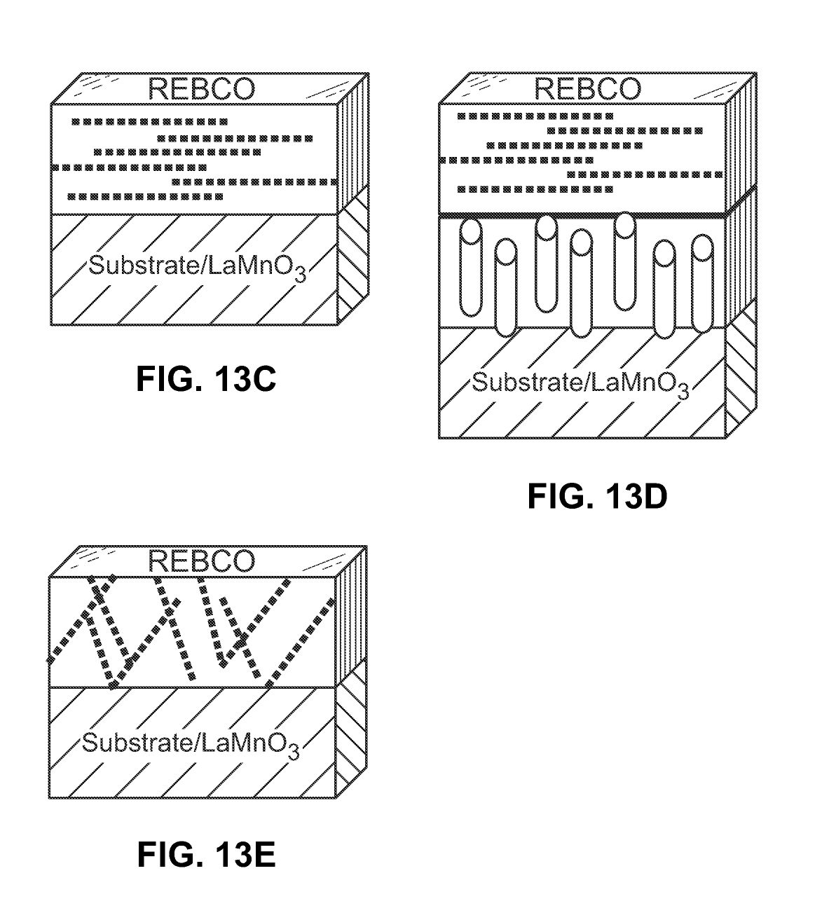

FIGS. 9A-B are a plot of T_{c} vs. Nb-concentration (mol %) and a plot of J_{c} vs. Nb-concentration. FIG. 9A shows that T_{c} values are relatively unaffected with increasing Nb amounts, and remain above 88 K at 10 mol % (FIG. 13A). FIG. 9B shows that J(sf, 77 K) drops sharply for 5<Zr(mol %)≦10, but a 1-2% variation in T_{c} cannot account for the >70% drop in J_{c} (sf.) at 10 mol %.

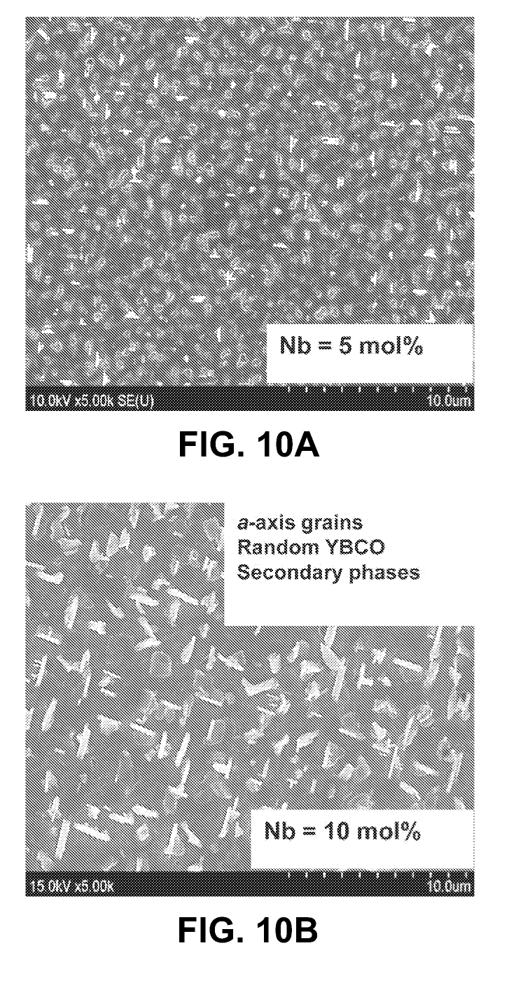

FIGS. 10A-B depict misoriented and/or randomly oriented grain content with increasing Nb content and demonstrate the degradation in superconductor properties with respect to an increase in Nb content. FIG. 10A illustrates 5 mol % Nb. FIG. 10B illustrates the appearance of a-axis grains and random YBCO and secondary phases at increased (10 mol %) Nb concentration.

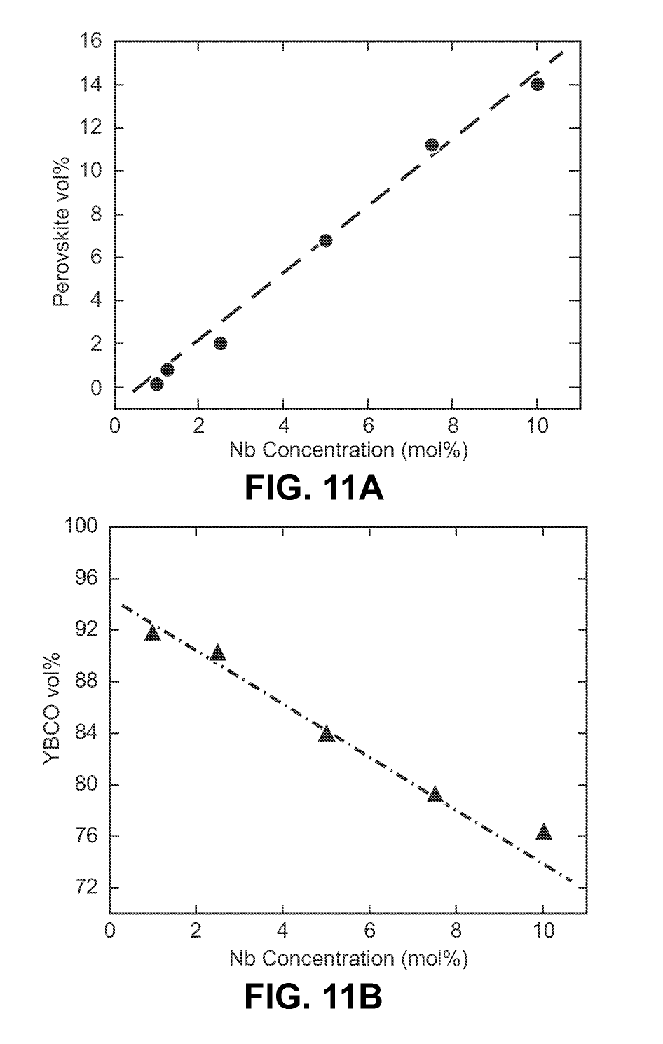

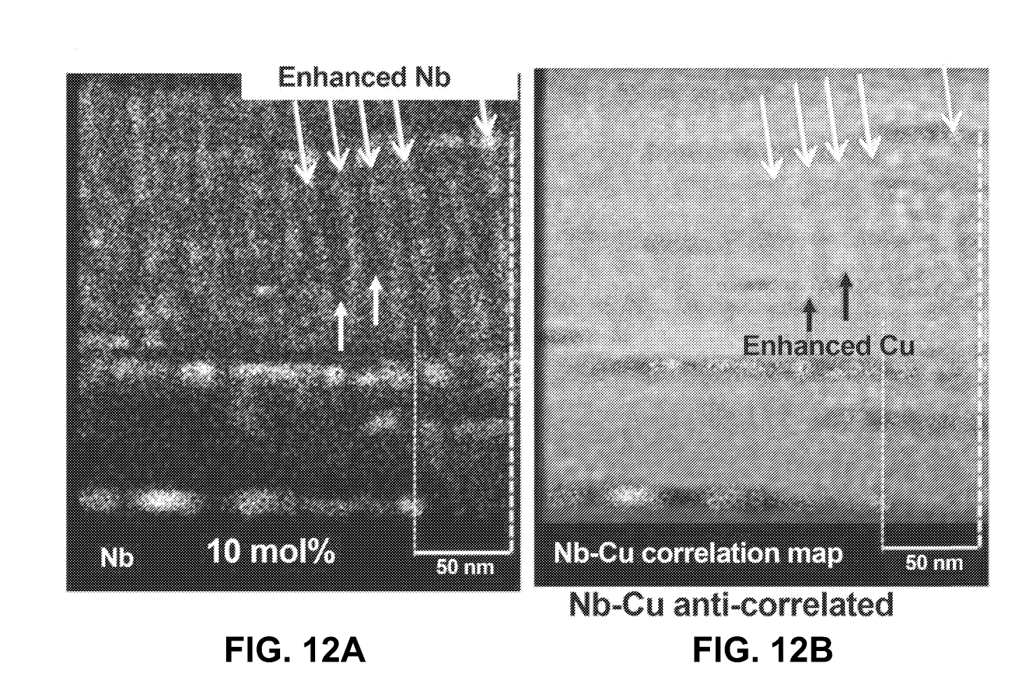

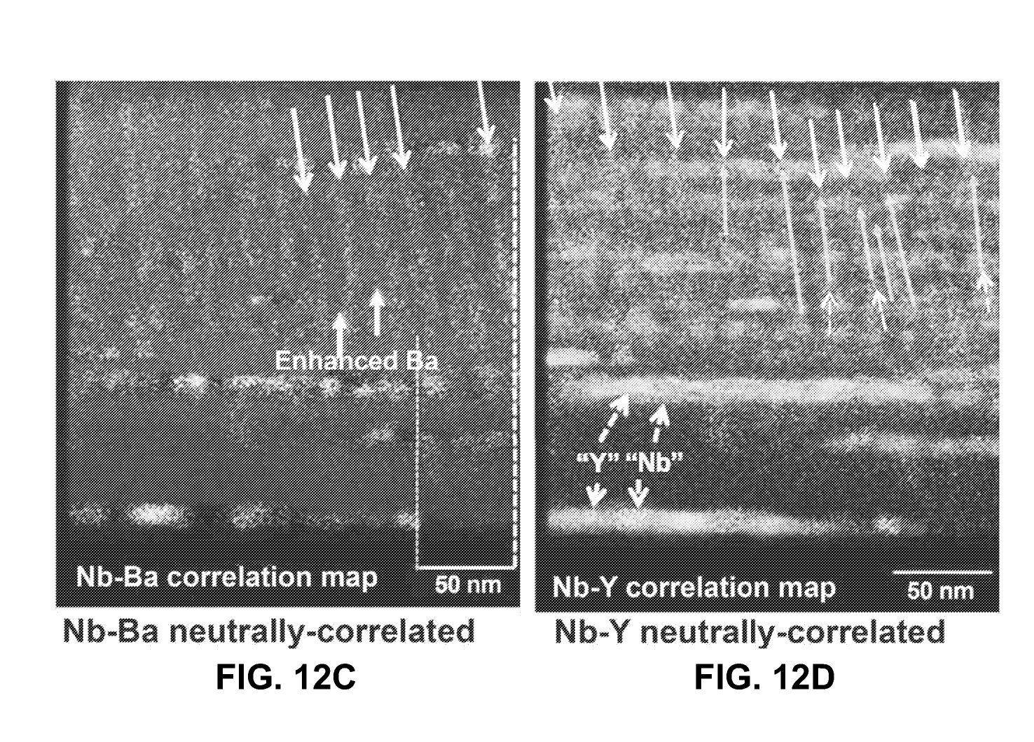

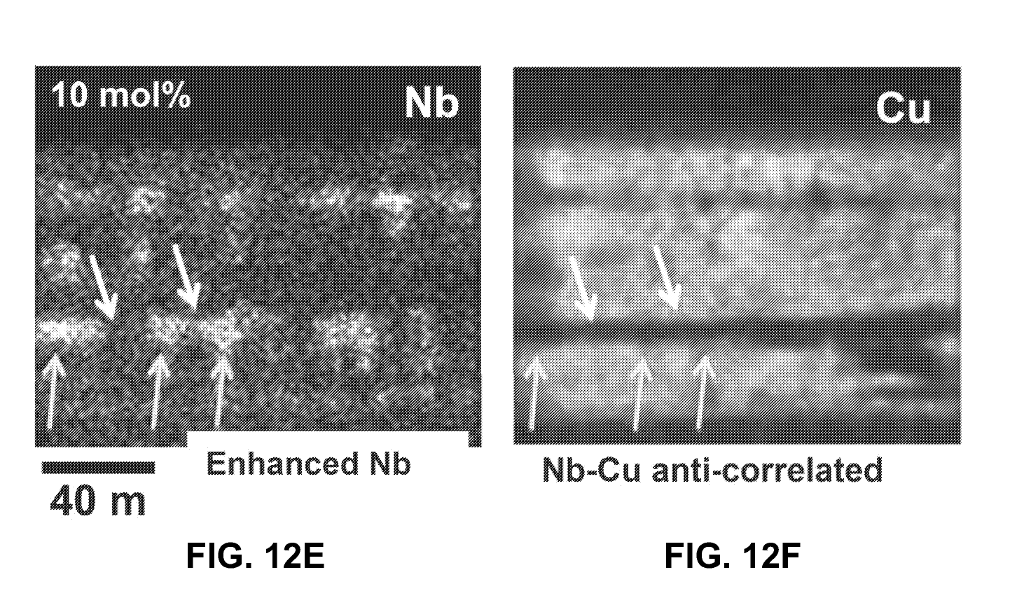

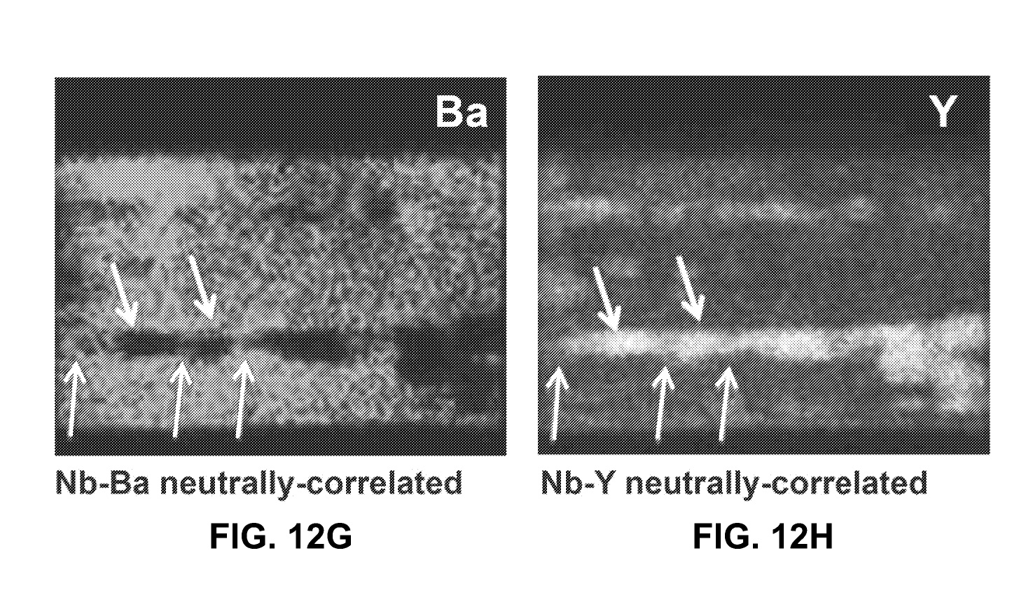

FIGS. 11A-B are a plot of perovskite (YBa₂NbO₆) vol % vs. Nb concentration (mol %) and a plot of YBCO vol % vs. Nb concentration (mol %). FIG. 11A illustrates that with increased Nb doping, the perovskite vol % increases. The increased amount of Nb tends to tie up more and more of the Y and Ba, leaving less and less to form YBCO, as shown in FIG. 13B. FIGS. 12A-H are spectral images showing Y—Ba—Nb—O columnar defects and Y₂O₃ & Y—Ba—Nb—O planar defects. FIGS. 12A-D show columnar defects resulting from enhanced Nb, that Nb—Cu are anti-correlated, and that Nb—Ba and Nb—Y are neutrally correlated. FIGS. 12E-H show Y₂O₃ and Y—Ba—Nb—O planar defects with enhanced Nb, that Nb—Cu are anti-correlated, and that Nb—Ba and Nb—Y are neutrally-correlated.

FIGS. 13A-E are schematic diagrams depicting various doping schemes. FIG. 13A illustrates a standard undoped REBCO/LaMnO₃/IBAD-MgO architecture. FIG. 13B illustrates a Nb-doped REBCO/LaMnO₃/IBAD-MgO architecture, with columns representing columnar defect structures. FIG. 13C illustrates a Nb-doped REBCO/LaMnO₃/IBAD-MgO architecture, with lines representing planar defect structures. FIG. 13D illustrates Nb-doped hybrid REBCO/LaMnO₃/IBAD-MgO architecture with both columnar (columns) and planar (lines) defect structures. FIG. 13E illustrates a Nb-doped REBCO/LaMnO₃/IBAD-MgO architecture, with tilted lines representing defect structures having an angular splay.

The XRD, XAS, and TEM analytical results point to the possibility for the formation of a secondary phase comprising one of the elements Nb, Ta, or V, or combinations thereof. Such secondary phase constituents can in the case of Nb include YBa₂NbO₆ and BaₓNb_{y}O_{z}. It is possible to selectively adjust the overall in-field properties of MOCVD-HTS wires to meet the needs of sundry and various applications including, but not limited to motors, generators, transformers, fault current limiters, magnets for high energy particle accelerators, transmission cables, and the like. This can be accomplished by adjusting precursor concentration levels, stoichiometry, flow rates, deposition pressures and deposition temperatures. In general, it has been observed that increasing the presence of RE compounds adds to planar defects. The presence of Sn and Zr tends to enhance the formation of columnar defects. The doping of Ta and Nb into the superconductor layer can in some circumstances enhance both planar and columnar defects. Varying precursor compositions and deposition conditions can be used to obtain differing combinations of particulate or columnar defects, as well as the size, concentration, and/or orientation of the defects.

While there has been shown and described what are at present considered to be examples of the invention, it will be obvious to those skilled in the art that various changes and modifications can be prepared therein without departing from the scope of the inventions defined by the appended claims.

What is claimed is:

1. A method of making a superconducting article comprising the steps of:
providing a substrate having an uniaxially or biaxially textured surface; and
using MOCVD to deposit onto said surface an epitaxial layer of material comprising REBCO and a secondary phase comprising a dopant, said dopant comprising at least one element selected from the group consisting of Nb, Ta and V, and combinations thereof.

2. The method of claim 1, further comprising:
providing a precursor solution comprising precursor compounds for RE, Ba, Cu and the dopant.

3. The method of claim 2, wherein the precursor solution comprises a precursor compound selected from the group consisting of tris(2,2,6,6-tetramethyl-3,5-heptanedionato)yttrium; bis(2,2,6,6-tetramethyl-3,5-heptanedionato)barium phenanthroline adduct; bis(2,2,6,6-tetramethyl-3,5-heptanedionato)copper; tetrakis(2,2,6,6-tetramethyl-3,5-heptanedionato)niobium; and combinations thereof.

4. The method of claim 2, wherein the precursor solution comprises a precursor compound selected from the group consisting of Pentakis(dimethylamino)tantalum(V);
Cyclopentadienylniobium(V) tetrachloride: Niobium(V) ethoxide; Niobium(IV) 2-ethylhexanoate; Pentakis(dimethylamino)niobium(V);
Tetrachlorobis(tetrahydrofuran)niobium(IV); t-Butylimidotris(dimethylamido)tantalum(V);
Pentakis(dimethylamino)tantalum(V); Pentamethylcyclopentadienyltantalum tetrachloride;
Tantalum(V) methoxide; Tantalum(V) tetraethoxyacetylacetonate; Tantalum(V) (tetraethoxy);
Vanadium(III) acetylacetonate; Vanadyl naphthenate; and Cyclopentadienylvanadium tetracarbonyl; and combinations thereof.

5. The method of claim 2, wherein the precursor compound is dissolved in a solvent.

6. The method of claim 2, wherein RE is Y and the stoichiometry of Y, Ba and Cu in the precursor solution is Y_{1±0.5}, Ba_{2±0.5}, Cu_{3±0.8}.

7. The method of claim 1, wherein the secondary phase comprises at least one of YBa₂NbO₆ and BaₓNb_{y}O_{z}, where x=0-14.66, y=1-17, and z=3-32.

8. The method of claim 1, wherein the secondary phase comprises at least one of YBa₂TaO₆, BaₓTa_{y}O_{z}, where x=0-7, y=1-6, z=1-16, YₓTa_{y}O_{z} where x=1-10, y=1-7, z=3-25, and Ba(Y_{0.5}Ta_{0.5})O₃.

9. The method of claim 1, wherein the secondary phase comprises at least one of YBa₂VO₆, YBa₂V₃O₁₁, BaₓV_{y}O_{z}, where x=0-8, y=1-12, z=0.2-30, and YₓV_{y}O_{z} where x=1-10, y=1-2, and z=4-20.

10. The method of claim 1, wherein the Nb content is between 0.1 mol % and 50 mol %, with respect to the moles of REBCO.

11. The method of claim 1, wherein the Nb content is between 0.1 mol % and 10 mol %, with respect to the moles of REBCO.

12. The method of claim 1, wherein said secondary phase comprises a double perovskite.

13. The method of claim 1, wherein said using MOCVD, comprises:
vaporizing a precursor solution; and
mixing vapor from said precursor solution with oxygen.

14. The method of claim 13, wherein an oxygen flow rate of said mixing step is between 1.1-1.7 liter/min.

15. The method of claim 13, wherein an oxygen flow rate of said mixing step is between about 1.1-1.2 liters/min.

16. The method of claim 1, wherein a deposition pressure of said MOCVD is between 1-5 Torr.

17. The method of claim 1, wherein a deposition pressure of said MOCVD is between 2-3 Torr.

18. The method of claim 1, wherein a deposition temperature of said MOCVD is between about 920-975° C.

19. The method of claim 16, wherein a deposition temperature of said MOCVD is between about 850-980° C.

20. The method of claim 1, wherein a precursor delivery rate of said MOCVD is between about 1-10 mliter/min.

21. The method of claim 1, wherein a precursor delivery rate of said MOCVD is between about 1-3 muter/min.

22. The method of claim 1, wherein a deposition rate of said MOCVD is between about 0.01-2.0 micron/min.

23. The method of claim 1, wherein a deposition rate of said MOCVD is between about 0.2-0.3 micron/min.

24. The method of claim 1 wherein at least a portion of said substrate comprises at least one of component selected from the group consisting of stainless steel, Cu, Ni, Fe, Al, Ag, and alloys of any of the foregoing.

25. The method of claim 1 wherein at least a portion of said substrate comprises at least one of the group consisting of Ni—W, Ni—Cr, Ni—Cr—W, Ni—Cr—V, Ni—V, and Ni—Mn.

26. The method of claim 1 wherein at least a portion of said substrate comprises at least one of the group consisting of MgO, SrTiO₃, and REAlO₃, where RE comprises at least one rare-earth element.

27. The method of claim 1 wherein REBCO is REBa₂Cu₃O₇.

28. A superconducting article produced by the process of:
providing a substrate having a uniaxially or biaxially textured surface; and
using MOCVD to deposit onto said surface an epitaxial layer of material comprising REBCO and a secondary phase comprising a dopant, said dopant comprising at least one element selected from the group consisting of Nb, Ta and V.
